(19) United States
(12) Patent Application Publication
(10) Pub. No.: US 2023/0122858 A1
(43) Pub. Date: Apr. 20, 2023

(54) Method of Embedding a Multi-Layer Lithium Ion Battery on a Flexible Printed Circuit Board

(71) Applicant: Compass Technology Company Limited, Shatin (HK)

(72) Inventors: Kelvin Po Leung Pun, Hong Kong (HK); Chee Wah Cheung, Hong Kong (HK); Jason Rotanson, Hong Kong (HK); Yuen Yung Chan, Hong Kong (HK); Wing Lung Hon, Hong Kong (HK); Yam Chong, Hong Kong (HK); Wai Yin Wong, Hong Kong (HK); Shengbo Lu, Hong Kong (HK); Chenmin Liu, Hong Kong (HK)

(21) Appl. No.: 17/501,297

(22) Filed: Oct. 14, 2021

(51) Int. Cl. H01M 50/109; H05K 1/02; H01M 10/0525; H01M 50/186; H01M 10/0585; H01M 50/191; H01M 50/197; H01M 50/119; H01M 50/124; H01M 50/121; H01M 50/193; H01M 4/62; H01M 4/66; H01M 4/587

(52) U.S. Cl. CPC H01M 50/109; H05K 1/0277; H01M 10/0525; H01M 50/186; H01M 10/0585; H01M 50/191; H01M 50/197; H01M 50/119; H01M 50/124; H01M 50/121; H01M 50/193; H01M 4/625; H01M 4/622; H01M 4/661; H01M 4/587; H01M 2220/30

(57) ABSTRACT

A flexible printed circuit board with a multi-layer all solid-state lithium ion battery printed thereon is described. A flexible printed circuit board comprises at least one electrically insulating liquid crystal polymer or polyimide layer and at least one electrically conductive metal layer. The multi-layer all solid-state lithium ion battery comprises at least one anode, at least one cathode, and at least one UV curable solid electrolyte therebetween. The battery is encapsulated between the flexible printed circuit board and a layer of laminated aluminum foil on top of the multi-layer all solid-state lithium ion battery and adhered directly to the flexible printed circuit board.

### RELATED PATENT APPLICATION

This Patent Application is related to U.S. patent application Ser. No. 16/801,779, filed on Feb. 26, 2020, and now U.S. Pat. No. 10,917,973, assigned to the same assignee as the present application, which is herein incorporated by reference in its entirety.

### TECHNICAL FIELD

This application relates to integrated circuit boards, and more particularly, to embedding a multi-layer lithium ion battery on flexible printed circuit boards.

### BACKGROUND

With the emergence of Internet of Things (IoTs) and 5G networking technologies, more and more devices are being interconnected to communicate with each other to make decisions and improve people's lives. Future generations of devices are expected to possess attributes such as low cost, small form factor, high reliability, flexible/conformable, and low power consumption. Flexible electronics have become ubiquitous in fulfilling the aforementioned challenges. In particular, System in Package (SiP) architecture is the packaging technology of choice for high level of device integration such as antennas, microprocessors, and sensors, as well as batteries to enable self-powered devices.

A battery is an essential component to power portable electronic devices. Conventionally electronic devices have been using commercial batteries such as prismatic, cylindrical, and coin cells. These batteries are not suitable to power flexible electronics due to their bulkiness, rigidity, and safety concerns. Power sources for flexible electronic devices should also conform to the devices' requirements such as ultra-thin, ultra-light, mechanical conformity, and safety under mechanical loading.

Integrating a flexible battery directly onto a flexible substrate is an attractive solution to future generations of devices. It offers many advantages such as reduced form factor, reduced cost, and process simplification. The integrated flexible battery can be used for applications requiring power management and RF (radio frequency) communication such as a smart card, wearable devices, and internet of things (IoTs).

Various references disclose lithium ion batteries including U.S. Patent Applications 2020/0176752 (Birt et al) and 2020/0321653 (O'Neill et al) and U.S. Pat. Nos. 10,290,906 (Wang) and 10,804,566 (Xia et al).

### SUMMARY

A principal object of the present disclosure is to provide a method of embedding a multi-layer lithium ion battery on a flexible printed circuit board.

Another object of the disclosure is to provide a flexible printed circuit board having a multi-layer all solid-state lithium ion battery embedded therein.

According to the objects of the disclosure, a flexible printed circuit board with a multi- layer all solid-state lithium ion battery embedded therein is achieved. The multi-layer all solid-state lithium ion battery comprises at least one anode, at least one cathode, and at least one UV curable solid electrolyte therebetween. The battery is encapsulated between a flexible printed circuit board and a layer of laminated aluminum foil on top of the multi-layer all solid-state lithium ion battery and adhered directly to the flexible printed circuit board.

Also according to the objects of the disclosure, a flexible printed circuit board with a multi- layer all solid-state lithium ion battery embedded therein is achieved. A flexible printed circuit board comprises at least one electrically insulating liquid crystal polymer or polyimide layer and at least one electrically conductive metal layer. The multi-layer all solid-state lithium ion battery comprises a plurality of anodes, each anode having an anode tab not coated with anode material, a plurality of lithium ion metal oxide cathodes, each cathode having a cathode tab not coated with cathode material, and at least one UV curable solid electrolyte therebetween. Electrical connection is made between the anode tabs and a first metal pad on the flexible printed circuit board wherein the first metal pad works as a negative terminal of the battery. Electrical connection is made between the cathode tabs and a second metal pad on the flexible printed circuit board wherein the second metal pad works as a positive terminal of the battery. An encapsulation layer of laminated aluminum foil is on top of the multi-layer all solid-state lithium ion battery and adhered directly to the flexible printed circuit board encapsulating the multi-layer all solid-state lithium ion battery between the flexible printed circuit board and the laminated aluminum foil.

Also according to the objects of the disclosure, a method of fabricating a multi-layer solid-state lithium ion battery embedded in a flexible printed circuit board is achieved. At least one anode is fabricated on both sides of a copper foil, leaving an anode tab without anode coating. At least one lithium metal oxide cathode is fabricated on both sides of an aluminum foil, leaving a cathode tab without cathode coating. Anodes and cathodes are alternately stacked on a bottom layer of encapsulation on a flexible printed circuit board with a UV-curable composite solid electrolyte in between each layer to form a multi-layer structure. The anode tab of each of the stacked anodes is electrically connected to a first metal pad on the flexible printed circuit board by electrically conductive adhesive tape, wherein the first metal pad works as a negative terminal allowing electrons to flow out of the anodes to the flexible printed circuit board during battery discharge to drive chips on the flexible printed circuit board. The cathode tab of each of the stacked cathodes is electrically connected to a second metal pad on the flexible printed circuit board by electrically conductive adhesive tape, wherein the second metal pad works as a positive terminal allowing electrons to flow into the cathodes during battery discharge to drive chips on the flexible printed circuit board.

### BRIEF DESCRIPTION OF THE DRAWINGS

In the accompanying drawings forming a material part of this description, there is shown:

FIG. 1 is a schematic diagram of a preferred embodiment of a two-level lithium ion battery of the present disclosure.

FIG. 2 is a cross-sectional representation of a preferred embodiment of a flexible printed circuit board of the present disclosure taken along line 2A-2A′ of FIG. 1.

FIG. 3 is a cross-sectional representation of a preferred embodiment of a flexible printed circuit board of the present disclosure taken along line 3A-3A′ of FIG. 1.

FIG. 4 is a cross-sectional representation of a preferred embodiment of a laminated aluminum layer of the present disclosure.

FIG. 5 is a cross-sectional representation of a preferred embodiment of a two-level lithium ion battery integrated into a flexible printed circuit board that has been assembled with active and passive components, taken along line 5A-5A′ of FIG. 1.

FIG. 6 is a graphical representation of the charge-discharge curve and the corresponding nominal voltage of a preferred embodiment of the present disclosure.

FIG. 7 is a graphical representation of a cycling test of a preferred embodiment of the present disclosure.

### DESCRIPTION OF THE PREFERRED EMBODIMENTS

The present disclosure describes flexible printed circuit boards with flexible multi-layer all solid-state lithium ion batteries directly printed onto them. Flexible electronics have a small form factor. They typically have a high routing density and are foldable and bendable.

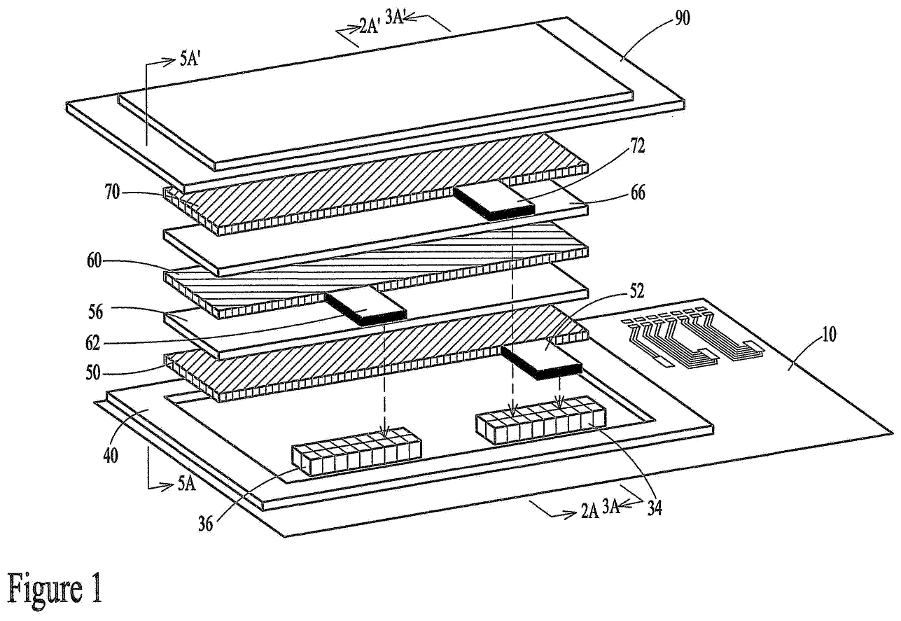

Referring now more particularly to FIGS. 1-5, the multi-layer all solid-state lithium ion battery on a flexible printed circuit board will be described. FIG. 1 is an exploded schematic diagram of the electrochemical multi-layer lithium ion battery of the present disclosure. Anodes and cathodes with tabs are alternately stacked on a flexible printed circuit board 10 with a UV-curable composite solid electrolyte in between to form a multi-layer structure. Tabs of the anodes are electrically connected to one metal pad on the flexible printed circuit board by electrically conductive adhesive tape and work as a negative terminal allowing electrons to flow out of the anode to the flexible printed circuit board during battery discharge to drive chips on the board. Tabs of the cathodes are electrically connected to another metal pad on the flexible printed circuit board by electrically conductive adhesive transfer tape and work as a positive terminal allowing electrons to flow into the cathode during battery discharge to drive chips on the board.

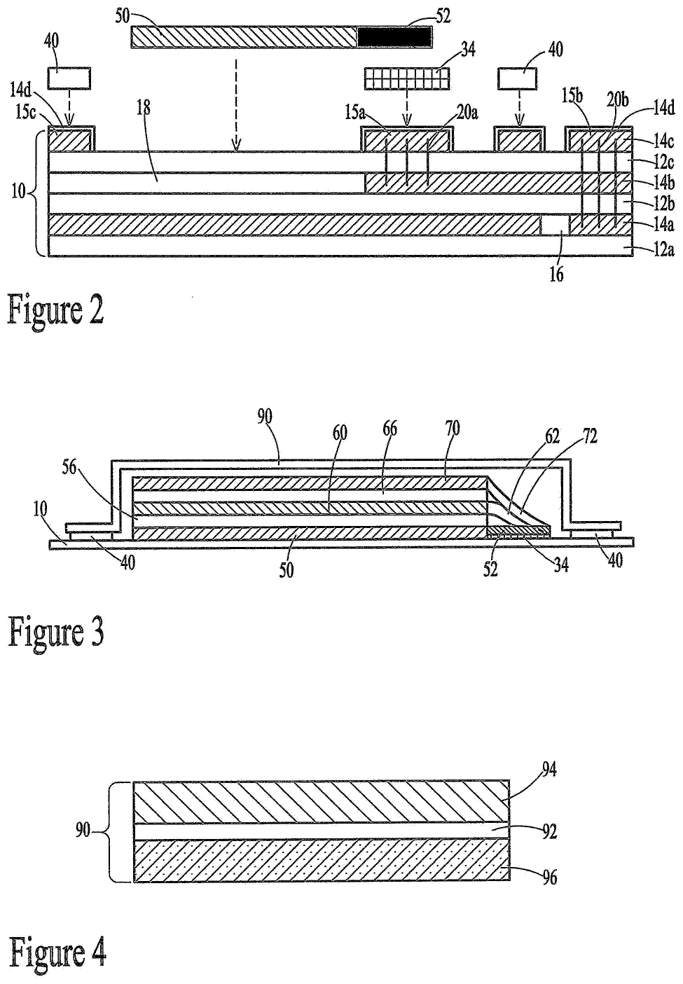

FIG. 2 shows a portion of a cross-section of the flexible printed circuit board 10, taken along the line 2A-2A′ of FIG. 1. The flexible printed circuit board 10 comprises electrically insulating liquid crystal polymer and/or polyimide layers and conductive metal layers with surface-finishing layers. Liquid crystal polymer and/or polyimide layers 12a, 12b, and 12c each have a thickness of between about 10 and 50 μm. 16 and 18 are glue or adhesive for layers 12a, 12b, and 12c.

Conductive metal layers 14a, 14b, and 14c are formed on each insulating layer. The metal layers comprise copper, nickel, palladium, gold, tin, silver or ruthenium or a combination thereof, having a thickness of between about 10 and 50 μm. The topmost metal layer 14c has a surface-finishing layer 14d thereon to provide resistance against oxidation. The surface finishing layer may be nickel, palladium, gold, tin, silver, aluminum, and ruthenium or a combination of thereof.

The combination of materials including the liquid crystal polymer, polyimide, and metal layers have a water vapor absorption rate no higher than 1×10⁻³ g·m⁻²·per day.

There may be more or fewer than the three insulating and conductive metal layers shown. The flexible printed circuit board having at least one insulating layer and at least one conductive metal layer provides encapsulation of the battery to provide high resistance from water and oxygen.

FIG. 2 shows that the metal layers are connected by metal filled via holes 20a and 20b to form two separate metal pads 15a and another metal pad not shown in this figure. FIG. 1 shows electrically conductive adhesive tape 34 on top of metal pad 15a and electrically conductive adhesive tape 36 on top of the second metal pad, not shown. The two metal pads are not electrically connected to each other. A current collector of electrodes will be attached to each of the two metal pads by electrically conductive adhesive tape. The metal pads work as the positive and negative terminals of the battery by connecting with electrically conductive metal traces (62 and 52, for example) of the positive and negative terminals of the flexible printed circuit board respectively. No external connection or electrical contact is needed to connect the flexible printed circuit board and the battery.

An electrode 50 with tab 52 is shown. Electrically conductive adhesive tape 34 connects the tab 52 to the electrically conductive metal trace 15a . The electrically conductive adhesive tape has a preferred thickness of between about 30 and 70 μm and should have a contact resistance of less than 0.3 Ω. The electrically conductive adhesive tape 34 (and 36 in FIG. 1) is conductive to allow electrons to pass through connecting the PCB 10 and the electrode tab 52.

Returning to FIG. 1, there is shown a ring of adhesive 40 on metal traces 15c (in FIG. 2). Adhesive 40 comprises acrylic, cast polypropylene, epoxy, polyurethane or a combination thereof. This resin adhesive 40 is not conductive. It provides for sealing between aluminum foil 90 on top of the battery and the PCB 10 on the bottom of the battery to prevent moisture and oxygen from penetrating into the battery cell.

Now the layers of the battery will be fabricated on the flexible printed circuit board 10. Anodes 50 and 70 are fabricated on both sides of a copper foil, leaving tabs 52 and 72, respectively, without the anode coating. The anodes 50 and 70 comprise an artificial graphite in an amount of 85-90% by weight, a carbon conductive agent of Super P and KS6 in an amount of 1-8% and 1-6%, respectively, and a polyvinylidene fluoride polymer binder in an amount of 1-2%. Other anode active materials such as silicon carbon composite, graphene oxide, natural graphite, or mixtures thereof may also be used. Styrene-Butadiene Rubber (SBR) and Carboxymethyl Cellulose (CMC) may be used as a binder in place of the polyvinylidene fluoride polymer binder.

Lithium metal oxide cathode 60 is fabricated on both sides of an aluminum foil, leaving a tab 62 without cathode coating. The lithium-metal-oxide cathode 62 comprises a lithium metal oxide such as LiNiₓCo_{y}Mn_{z}O₂, LiNiₓCo_{y}Al_{z}O₂, LiCoO₂, xLi₂MnO₃·(1−x)LiMO₂ (M═Mn, Ni, Co), LiMPO₄(M═Fe and/or Mn), or LiMn₂O₄ in an amount of 80-98%, a carbon conductive agent of Super P and KS6 in an amount of 1-5% and 1-5%, respectively, and a polyvinylidene fluoride polymer binder in an amount of 1-10%.

Anodes 50 and 70 and cathode 60 with tabs are alternately stacked on the bottom layer with UV-curable composite solid electrolyte in between to form a multi-layer structure. Multiple layers of anodes and cathodes may be stacked alternately with electrolyte layers therebetween to form the multi-layer lithium ion battery of the present disclosure. FIG. 1 shows, for example, two anodes, one cathode, and two electrolyte layers. More or fewer anodes and/or cathodes may be stacked. FIG. 3 is a cross-section taken on line 3A-3A′ of FIG. 1.

A UV-curable composite solid electrolyte (56, 66) is fabricated on either side or both side of the electrodes and is cured by the UV light with a wavelength of the range of 200-400 nm within 1 minute. The UV-curable composite solid electrolyte has a room temperature ionic conductivity of no less than 1*10⁻⁴ S/cm after curing.

The tabs 52, 72 of anodes 50, 70 are electrically connected to one metal pad 15a on the flexible printed circuit board 10 by electrically conductive adhesive tape 34. The tabs electrically connected to the metal pad 15a work as a negative terminal allowing electrons to flow out of the anodes 50, 70 to the flexible printed circuit board during battery discharge to drive chips on the board. It can be seen in FIG. 3 that tab 72 of the upper anode 70 is longer than tab 52 so as to reach to adhesive tape 34. It can be seen in FIG. 1 that tabs 52 and 72 will contact adhesive tape 34 adjacent to each other.

The tab 62 of cathode 60 is electrically connected to another metal pad (shown in FIG. 1) on the flexible printed circuit board by electrically conductive adhesive tape 36. The tab 62 electrically connected to the metal pad works as a positive terminal allowing electrons to flow into the cathode during battery discharge to drive chips on the board.

When all the battery layers have been stacked on the printed circuit board 10, a laminated aluminum foil layer 90 is formed as the top layer of the battery structure, as shown in FIGS. 1 and 3. FIG. 4 shows a cross-sectional representation of the laminated aluminum foil layer 90, shaped to encapsulate the battery. The laminated aluminum foil layer 90 consists of one aluminum layer 92 that is laminated between two insulating polymer composite layers, with the outer layer 94 comprising nylon, polyvinyl alcohol, or polyvinyl chloride and the inner layer 96 comprising polyester, cast polypropylene, or polyethylene, to provide high resistance from water and oxygen. All of these are adhesive. The inner layer 96 adheres to adhesive layer 40.

The adhesive composite layer 40 contains acrylic, cast polypropylene, epoxy, polyurethane or their combination, having a dielectric constant of less than 3 at a frequency of 10 GHz. The adhesive composite 40 is a thermosetting adhesive with a curing temperature in the range of 150 to 200° C. and should have a peeling strength of not less than 1 N/mm with the top and bottom layers of encapsulation.

The electrochemical multi-layer lithium ion battery of the present disclosure, as shown in FIG. 3, is encapsulated by the flexible printed circuit board 10 on the bottom, the composite adhesive layer 40 on the bottom perimeter of the battery and by a laminated aluminum foil layer on the top.

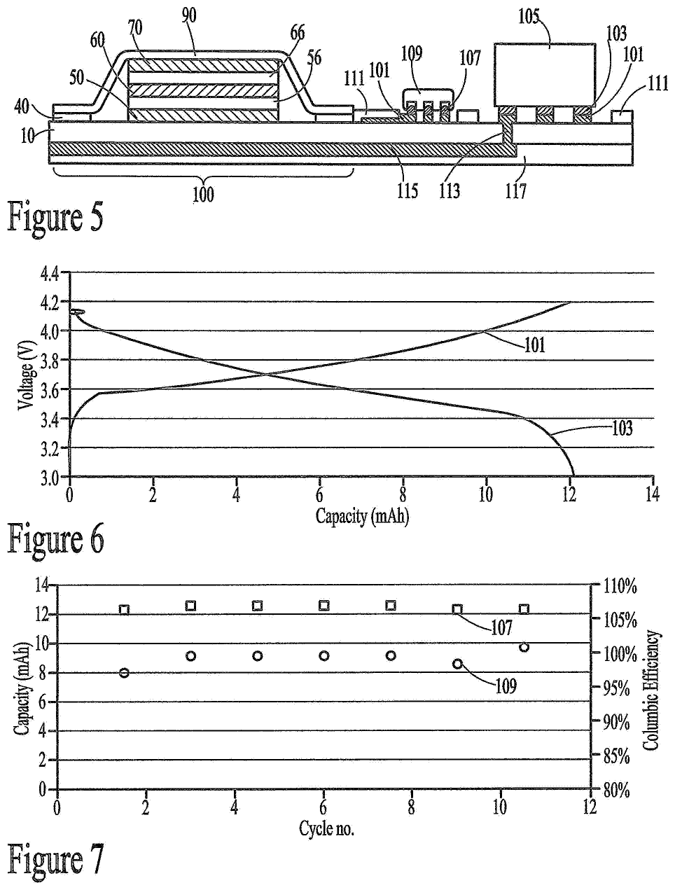

FIG. 5 illustrates the two anode-one cathode (2A1C) battery of FIG. 3 embedded on a flexible printed circuit board and assembled with active and passive electronic devices. For example, FIG. 5 illustrates a cross section taken along the line 5A-5A′ of FIG. 1. Battery 100 is shown embedded on PCB 10 and encapsulated with adhesive tape 40 and laminated Aluminum layer 90. Copper traces 101, for example, have been fabricated on the PCB 10 adjacent to the battery 100. For example, semiconductor die 105 is die attached to gold bumps 103 on copper traces 101. Passive component 109 is attached by solder bumps 107 to other copper traces 101. Copper via 113 through the PCB 10 and liquid crystal polymer or polyimide layer 117 electrically connects the semiconductor die 105 to trace 115. Trace 115 will connect to the battery 100 through the conductive adhesive tape 34 or 36, then further connect to the tab of the anode 52, 72, or the tab of the cathode 62, shown in FIG. 1. As FIG. 5 is a cross section across line 5A-5A′ of FIG. 1, the battery connection is not visible in this view.

FIG. 6 shows the charging curve 101 and discharging curve 103 of a 2A1C cell, as shown in FIG. 3 at an operation voltage in the range of 3V-4.4V, which indicates the nominal voltage of the battery is 3.7 V based on the calculated mean value of the voltage.

FIG. 7 illustrates the capacity of the battery of the present disclosure as a function of number of cycles run (107) and Columbic efficiency (%) as a function of number of cycles (109). This graph shows that the battery of the present disclosure has a cycle life of 100% and a Columbic efficiency of close to 100%.

The capacity of batteries having different numbers of anodes and cathodes would be different, but the Columbic efficiencies would be similar.

The electrochemical multi-layer lithium ion battery of the present disclosure has an aerial capacity density of 2.2 mAh/cm² and is capable of being cycled at a rate of no more than 0.2C. C-rate is a term commonly used in the field of batteries to denote the charge and discharge rates of the battery relative to its maximum capacity; in this case, 0.2 C means the charging current is 20% of the rated capacity over one hour.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A multi-layer all solid-state lithium ion battery, comprising:
a flexible printed circuit board;
said multi-layer all solid-state lithium ion battery comprising:
at least one anode;
at least one cathode; and
at least one UV curable solid electrolyte therebetween; and
an encapsulation layer of laminated aluminum foil on top of said multi-layer all solid-state lithium ion battery and adhered directly to said flexible printed circuit board encapsulating said multi-layer all solid-state lithium ion battery between said flexible printed circuit board and said laminated aluminum foil.

2. The battery according to claim 1 wherein said flexible printed circuit board comprises:
at least one electrically insulating liquid crystal polymer or polyimide layer; and
at least one electrically conductive metal layer.

3. The battery according to claim 2 wherein said liquid crystal polymer or polyimide layer has a thickness of between about 10 and 50 μm.

4. The battery according to claim 2 wherein said conductive metal layer has a thickness of between about 10 and 50 μm.

5. The battery according to claim 2 further comprising a surface-finishing layer on a topmost of said at least one conductive metal layer to provide resistance against oxidation, wherein said surface-finishing layer comprises: copper, nickel, palladium, gold, tin, silver, ruthenium or a combination of thereof.

6. The battery according to claim 1 wherein said flexible printed circuit board has a water vapor absorption rate no higher than 1×10⁻³ g·m⁻²·per day.

7. The battery according to claim 1 wherein said flexible printed circuit board comprises:
at least one electrically insulating liquid crystal polymer or polyimide layer; and
at least two conductive metal layers, wherein said conductive metal layers are separated from one another by said at least one electrically insulating liquid crystal polymer or polyimide layer, wherein said at least two conductive metal layers are electrically connected to each other by filled via holes, and wherein a first and a second separate metal pads are formed of a topmost said conductive metal layer wherein said first and second metal pads are not electrically connected to one another.

8. The battery according to claim 7 wherein said first and second metal pads work as positive and negative terminals of said battery by connecting with electrically conductive metal tabs of positive and negative terminals of said flexible printed circuit board respectively.

9. The battery according to claim 7 wherein:
a tab of said at least one anode is connected by electrically conductive adhesive tape to said first metal pad wherein said first metal pad acts as a negative terminal for said battery; and
a tab of said at least one cathode is connected by electrically conductive adhesive tape to said second metal pad wherein said second metal pad acts as a positive terminal for said battery.

10. The battery according to claim 9 wherein said electrically conductive adhesive tape has a thickness of between about 30 and 70 μm and a contact resistance less than 0.3 Ω.

11. The battery according to claim 1 wherein said laminated aluminum foil comprises:
one aluminum layer laminated between an inner and an outer insulating polymer composite layer, wherein said outer layer comprises nylon, polyvinyl alcohol, or polyvinyl chloride and wherein said inner layer comprises polyester, cast polypropylene, or polyethylene.

12. The battery according to claim 1 further comprising an adhesive composite to bond said flexible printed circuit board and said laminated aluminum foil.

13. The battery according to claim 12 wherein said adhesive composite comprises acrylic, cast polypropylene, epoxy, polyurethane or the combination thereof and wherein said adhesive composite surrounds a perimeter of a bottommost layer of said battery.

14. The battery according to claim 12 wherein said adhesive composite has a dielectric constant less than 3 at a frequency of 10 GHz.

15. The battery according to claim 13 wherein said adhesive composite is a thermosetting adhesive with a curing temperature in the range of between about 150 and 200° C. and has a peeling strength of not less than 1 N/mm with the top and bottom layers of encapsulation.

16. A method of fabricating an electrochemical multi-layer all solid-state lithium ion battery in between top and bottom layers of encapsulation comprising:
fabricating a plurality of anodes, each anode fabricated on both sides of a copper foil, leaving an anode tab without anode coating;
fabricating a plurality of lithium metal oxide cathodes, each cathode fabricated on both sides of an aluminum foil, leaving a cathode tab without cathode coating;
alternately stacking said anodes and said cathodes on a bottom layer of encapsulation on a flexible printed circuit board with a UV-curable composite solid electrolyte in between each layer to form a multi-layer structure;
electrically connecting said anode tab of each of stacked said anodes to a first metal pad on said flexible printed circuit board by electrically conductive adhesive tape, wherein said first metal pad works as a negative terminal allowing electrons to flow out of said anodes to said flexible printed circuit board during battery discharge to drive chips on said flexible printed circuit board; and
electrically connecting said cathode tab of each of stacked said cathodes to a second metal pad on said flexible printed circuit board by electrically conductive adhesive tape, wherein said second metal pad works as a positive terminal allowing electrons to flow into said cathodes during battery discharge to drive said chips on said flexible printed circuit board.

17. The method according to claim 16 wherein said UV-curable composite solid electrolyte is fabricated on either side or both sides of said anodes or cathodes and is cured by irradiating said composite solid electrolyte with UV light having a wavelength in the range of between about 200 and 400 nm for less than or equal to 1 minute.

18. The method according to claim 16 wherein said UV-curable composite solid electrolyte has a room temperature ionic conductivity of no less than 1*10⁻⁴ S/cm after curing.

19. The method according to claim 16 wherein said each of said anodes comprises an artificial graphite in a carbon conductive agent of Super P and KS6, and a polyvinylidene fluoride polymer or Styrene-Butadiene Rubber and Carboxymethyl Cellulose binder.

20. The method according to claim 19 wherein instead of artificial graphite, said anodes comprise silicon carbon composite, graphene oxide, natural graphite, or mixtures thereof.

21. The method according to claim 16 wherein said each of said lithium metal oxide cathodes comprises a lithium metal oxide comprising: LiNiₓCo_{y}Mn_{z}O₂, LiNiₓCo_{y}Al_{z}O₂, LiCoO₂, xLi₂MnO₃·(1−x)LiMO₂ (M═Mn, Ni, Co), LiMPO₄(M═Fe and/or Mn), or LiMn₂O₄, a carbon conductive agent of Super P and KS6, and a polyvinylidene fluoride polymer binder.

22. A multi-layer all solid-state lithium ion battery, comprising:
a flexible printed circuit board comprising:
at least one electrically insulating liquid crystal polymer or polyimide layer; and
at least one electrically conductive metal layer;
said multi-layer all solid-state lithium ion battery comprising:
at least one anode having an anode tab not coated with anode material;
at least one lithium ion metal oxide cathode having a cathode tab not coated with cathode material; and
at least one UV curable solid electrolyte between each anode and cathode;
electrical connection between said at least one anode tab and a first metal pad on said flexible printed circuit board wherein said first metal pad works as a negative terminal of said battery;
electrical connection between said at least one cathode tab and a second metal pad on said flexible printed circuit board wherein said second metal pad works as a positive terminal of said battery; and
an encapsulation layer of laminated aluminum foil on top of said multi-layer all solid-state lithium ion battery and adhered directly to said flexible printed circuit board encapsulating said multi-layer all solid-state lithium ion battery between said flexible printed circuit board and said laminated aluminum foil.

23. A method of fabricating a self-powered flexible circuit board package comprising:
providing a flexible printed board with a multi-layer all solid-state lithium ion battery according to claim 22; and
mounting a plurality of active and passive electronic devices on top of copper traces on said flexible printed circuit board wherein at least one of said active devices is connected to and powered by said multi-layer all solid-state lithium ion battery.
